(19) United States
(12) Patent Application Publication
(10) Pub. No.: US 2009/0114266 A1
(43) Pub. Date: May 7, 2009

(54) High concentration, spectrum spitting, broad bandwidth, hologram photovoltaic solar collector

(76) Inventors: Jonathan R. Biles, Vancouver, WA (US); J. Michael Halter, Beaverton, OR (US)

Correspondence Address: Jonathan R. Biles, 10710 SE Evergreen Hyw, Vancouver, WA, 98664, US

(21) Appl. No.: 12/286,924

(22) Filed: Oct. 2, 2008

Related U.S. Application Data
(60) Provisional application No. 60/997,441, filed on Oct. 3, 2007.

(51) Int. Cl. H01L 31/052

(52) U.S. Cl. 136/246

(57) ABSTRACT

An improved method of converting solar energy into electricity by spreading the solar spectrum and concentrating it onto solar cells that are band-gaped in the corresponding wavelength range. The spectrally separated solar energy can be concentrated into a normal rainbow line or spread out to individual regions. A low cost solar energy conversion collector results because concentration reduces the quantity of photovoltaic cells needed and spectral splitting increases the energy collected by using multiple appropriately band-gaped solar cells in the different wavelengths.

### RELATED APPLICATIONS

Applicant claims benefit of provisional application No. 60/997,441 filed on Oct. 3, 2007 by Jonathan R. Biles.

### REFERENCES CITED

### U.S. Patent Documents

| | | |
|---|---|---|
| 6,015,950 | Jan. 18, 2000 | Converse |
| 5,517,339 | May 14, 1996 | Riccobone & Ludman |
| 5,491,569 | Feb. 13, 1996 | Riccobone & Ludman |
| 6,469,241 B1 | Oct. 22, 2002 | Penn |

### Other Publications

Barnett et al, “Milestones Toward 50% Efficient Solar Cell Modules,” 22 nd European Photovoltaic Solar Energy Conference, Milan, Italy, 3 Sep. 2007
J. Ludman, Am. J. Physics, Vol. 50, No. 3, page 244-246, March 1982

### BACKGROUND

The cost of electricity produced by photovoltaic solar cells can be reduced by concentrating the energy of the sun onto fewer cells and by utilizing more of the solar spectrum by splitting the spectrum horizontally onto cells individually optimized for a small portion of the solar spectrum. A hologram paired with a Fresnel lens can be manufactured which will split the solar spectrum into multiple small portions of the solar spectrum and optically redirect the spectral bands onto cells with the appropriate band-gap.

### SUMMARY OF THE INVENTION

This disclosure combines unpowered gratings with a Fresnel lens to provide the optical power. Solar cells can be lined up in a single wideband spectrum or narrow bandwidths can be sent to spatially displaced cells.

### BRIEF DESCRIPTION OF THE DRAWINGS

FIG. 1 is a front view of the wideband generator.

FIG. 2 is a top view of the detection plane, perpendicular to the optical axis, onto which the spectral band is concentrated.

FIG. 3 is a top view of the detector plane with blue and green solar cells placed in blue and green light.

FIG. 4 is a blue and green grating with fringes.

FIG. 5 shows a grating being exposed.

FIG. 6 is a narrowband generator using a thick grating.

FIG. 7 is a top view of the solar cell plane with a narrow band of diffracted light.

FIG. 8 is double-exposed hologram-Fresnel lens being used, with monochromatic sunlight, to create two images of the sun, s1 & s2.

FIG. 9 shows two sun images separated by less than the sun's angular diameter, make the two images overlap.

FIG. 10 shows overlapped images of the sun, from red to blue, spread out continuously with the addition of more wavelengths.

FIG. 11 shows three solar cells placed in a doubly exposed wideband spectrum.

FIG. 12 shows solar cells electrically connected to match voltage and current output.

### DETAILED DESCRIPTION OF THE PREFERRED EMBODIMENT

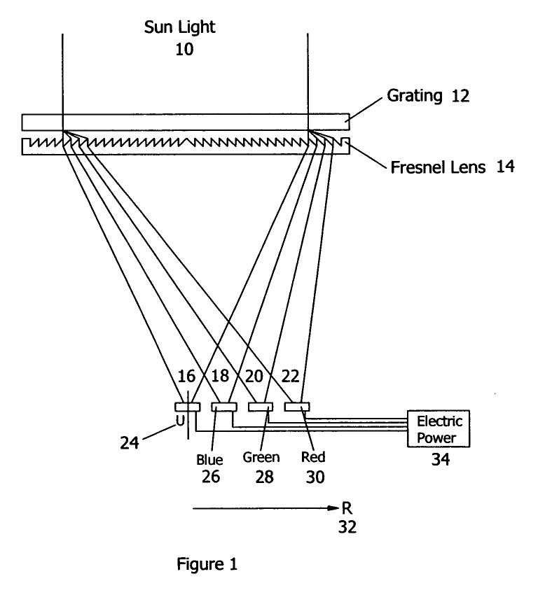

A wideband solar generator places solar cells side by side in a full spectrum. FIG. 1 is a front view of the wideband generator. The sunlight 10 is dispersed by the grating 12 and concentrated by the Fresnel 14 onto the solar cells 24, 26, 28, 30. The un-diffracted light U 16 is at the normal focus of the lens. The blue 18, green 20, and red 22 light absorbing solar cells are placed in their corresponding frequencies of light. The radial distance R 32 is shown from the un-diffracted image on the optical axis. The cells are shown connected to a power generating system 34, and should turn more than 40% of the sunlight that hits the lens into electricity.

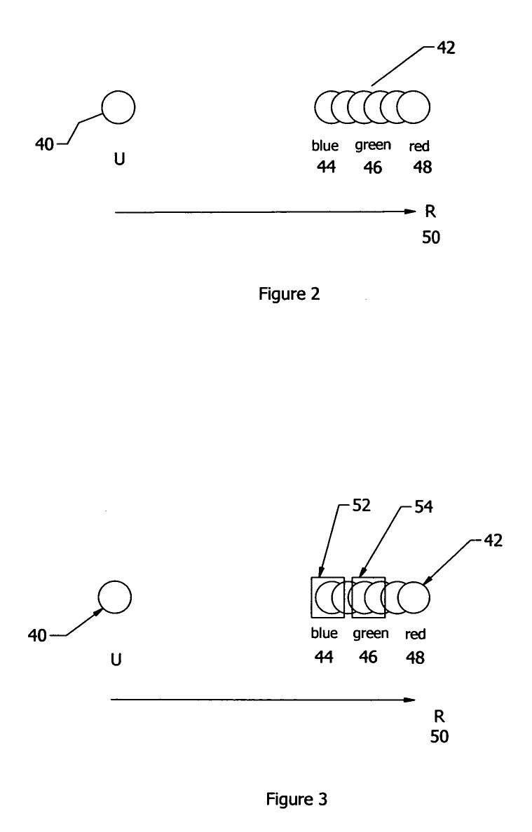

FIG. 2 shows a top view of the solar cell plane, perpendicular to the optical axis, onto which the spectral band is imaged. The multiple images of the sun 42 are meant to represent the spreading of the wavelengths. The red 48, green 46, and blue 44 images of the sun blur continuously. FIG. 3 is a top view of the solar cell plane with blue 52 and green 54 solar cells, shown as rectangles, placed in blue and green light.

A Fresnel is a convenient lens, but other means of optical power, such as a glass lens, could be used. Likewise, holographic gratings are used in this embodiment, but other gratings, such as surface relief gratings, could be used instead.

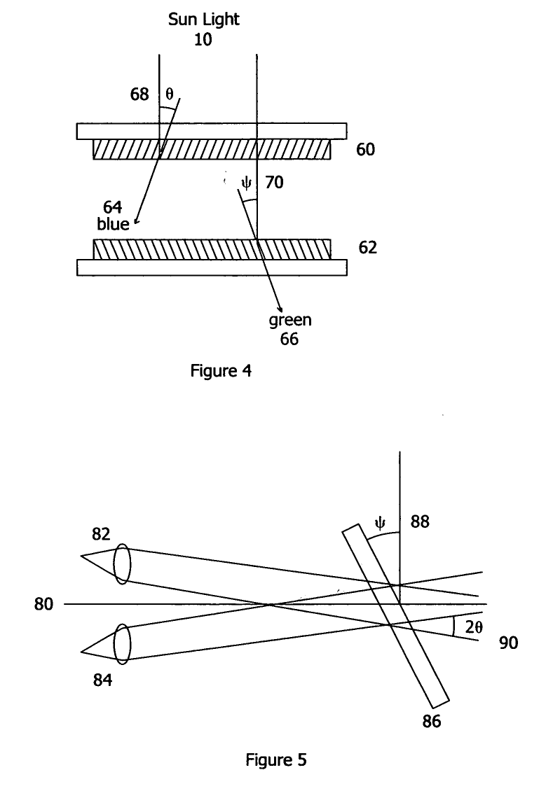

FIG. 4 shows a blue 60 and green 62 grating with fringes tilted at an angle theta and phi of around 10 degrees to diffract their wavelength bands off by 20 degrees away from the un-diffracted beam U. Because sunlight is usually incident perpendicular to the grating substrate, phi and theta are usually the same. If off-axis light is used instead, phi does not equal theta.

This type of uniform grating is easily made by interfering two collimated waves. The grating's bandwidth (to the blue side of each photocell's band-gap) is controlled by making the emulsion thicker for a narrow bandwidth, and thinner for a wide one. More than two gratings 82 84 can be placed in the same emulsion if needed.

FIG. 5 shows a grating being exposed. Two collimated beams from a laser are brought in at a half angle theta to make interference fringes. The interference angle theta can be varied to create a different fringe spacing d. The grating being exposed can be tilted at an angle phi to create fringes that are also tilted at the same angle to the surface of the hologram, as shown in FIG. 4. The hologram can be rotated about its perpendicular axis to create different sets of fringes

### Equations

Picking up from Ludman (Am. J. Physics, March 1982), we add simplifications that allow easier description:

1) small angles, sine=angle and cosine=1
2) materials have the same average index so n drops out.
3) angle in=angle out

### Grating:

θ=λ/2d

bandwidth:

Δλ=(d/T⊖)λ=1/2T(λ/θ)²

angular dispersion:

Δθ/Δλ=2θ/λ

Adding a lens makes an additional equation with the focal length multiplied. R is the distance from the axis as shown in FIGS. 1 and 2. Theta is the angle the light makes with the fringes, so 2*theta is the light's final angle with the optical axis.

Radial position:

R=2θf

### Wideband Version

In the wideband version, thickness T=10 microns, angle is theta ⅙ radian (=9.6 deg), and the wavelength is 0.5 micron. The bandwidth is:

Δλ=1/(2*10μ)*(0.5μ/(radian/6))²=0.45μ

This 450 nm bandwidth can diffract the whole visible spectrum.

The grating equation shows that for a fixed grating d, the diffraction angle theta is proportional to the wavelength, so if it diffracts 10 degrees at 500 nm, then 8 degrees for 400 nm, and 13 degrees for 650 nm.

This 400-650 nm is spread out on the detector 2*(13-8)=10 degrees. For a 100 mm Fresnel lens, multiplying by the focal length shows the spectrum's length to be 10/57.3*100 mm=17.4 mm. Longer focal length lenses would be proportionately larger, so a 1 meter lens has a 174 mm spectrum.

Individual solar cells are placed in this near two centimeter long spectrum. Solar cells of different band-gap are presently available such as GaAs, InP, GaN, and others. GaInN will possibly give band-gaps thru-out the visible, even variable band-gaps in the same substrate to match the spectrum. A series of individual detectors having band-gaps corresponding to diffracted spots, or a single detector with a spatially varying band-gap, can be used.

### Narrowband Version

A narrowband generator uses a thicker hologram, so the bandwidth becomes proportionately smaller. This allows different wavelength bands to be sent in different directions.

Increasing the angle could also be used to narrow the bandwidth, but this also increases the spectrum's angular size, requiring a larger solar cell. However, the bandwidth narrowing is a square function, and the dispersion is proportional, so increasing the angle narrows the bandwidth faster than it increases detector size. Since the goal in this version is to concentrate light onto a small detector, we will continue to use a low angle theta of ⅙ radian (9.55 deg).

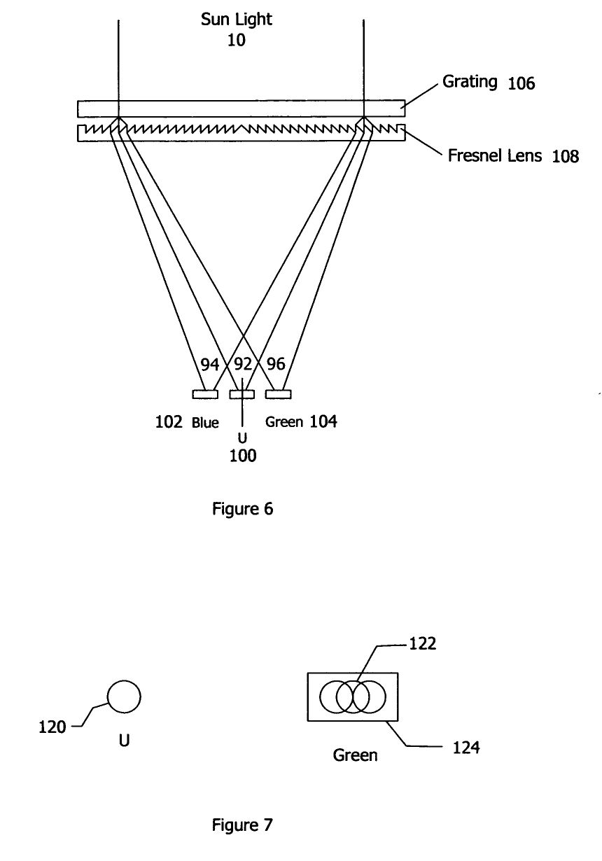

FIG. 6 is a narrowband generator using a thick grating to diffract blue light 20 degrees to one side 94 and the green to the other side 96 of the un-diffracted light U 92. Red, IR, or any other wavelength could be used. Since the grating has no optical power, it just sends a color band of collimated light in any direction. All three images on the detector plane are of the sun cast by the Fresnel lens after the grating. One is deep blue 94, one green 96, and the center un-diffracted light U 92 is orange.

Placement on opposite sides maximizes separation for 2 solar cells. With three cells, the gratings would be put 120 degrees apart to maximize separation. The grating for this arrangement would be made by rotating the grating 120 degrees about its perpendicular axis between the three exposures. The d would also be varied to control the wavelength band, and phi could remain the same, or change, for the three exposures.

Since bandwidth is inverse to thickness, if a 10 micron emulsion has a bandwidth of 450 nm, then a 50 micron one is 90 nm wide. 50 micron thick emulsions have been used by the inventor to make transmission holograms. A thinner one could be used if increasing diffraction angle were also used to decrease bandwidth, at the cost of a larger detector. FIG. 7 is a top view of the solar cell plane 124 with a narrow band of diffracted light 122.

### Uniformity

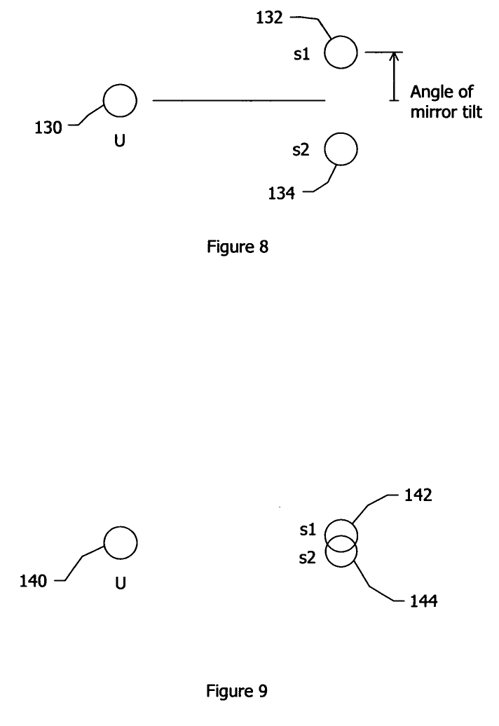

An additional disclosure increases the uniformity of the sunlight on the solar cells. By making two exposures of the holographic grating, the sun's intensity can be spread over the solar cell. In the exposure setup shown in FIG. 5, one of the collimated beams is tilted into the page for a first exposure, than tilted out of the page for a second exposure. When the final hologram-Fresnel lens was used with monochromatic sunlight, there would be two images of the sun, s1 & s2, as shown in FIG. 8. Their angular half separation would be the same as the mirror tilts if the reconstruction wavelength were the same as the laser construction wavelength. For different wavelengths, the separation is proportional to wavelength.

If these two images were separated by less than the sun's angular diameter, the two sun images overlap, and there would be a spreading out of the intensity as shown in FIG. 9.

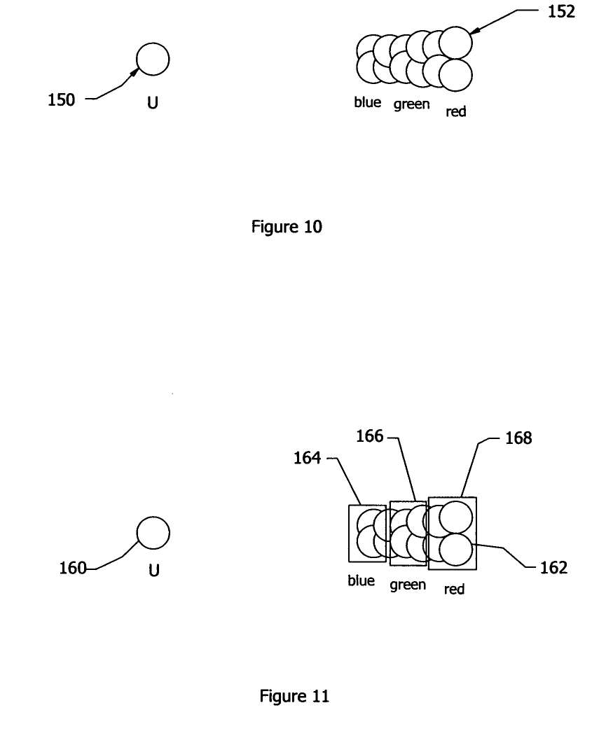

With the addition of more wavelengths, there would be multiple images of the sun, from red to blue as shown in FIG. 10, spread out continuously into a more uniform shape. The separation of the solar images is proportional to wavelength, so the outer red suns would be more separated than the inner blue suns, as shown in FIG. 10. The size of the sun's image, cast by the lens, would not depend on wavelength.

More complex exposure patterns can, when convolved with the sun's image, produce other uniform patterns.

FIG. 11 shows three solar cells 164 166 168, shown as rectangles, placed in a doubly exposed wideband grating.

### “Series-Parallel” Solar Cells

In prior art systems, to get higher efficiency, photocells that are sensitive to different colors of sunlight are stacked on top of each other. The cells are then connected in series to produce a larger total voltage. The currents must be the same.

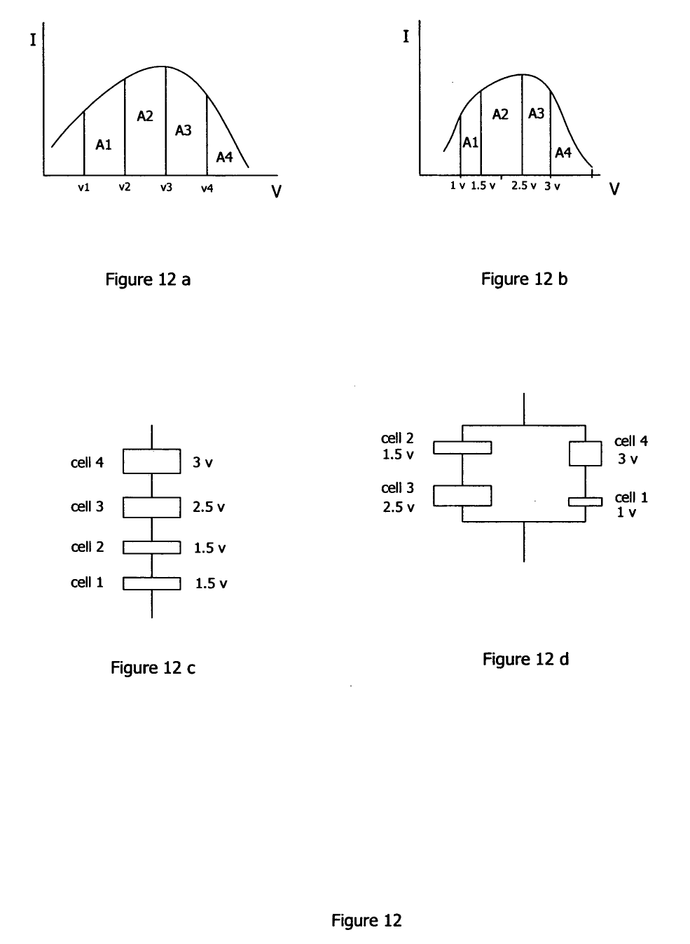

This disclosure uses the symmetrical shape of the solar spectrum to add the cells in series and parallel. In FIG. 12a the intensity of the sun is plotted against the energy of the light. In FIG. 12c, four different photocells are shown with band-gaps corresponding to infra-red, red, green, and blue. The voltages they produce are v1, v2, v3, and v4 and for a hypothetical example are around 1.0, 1.5, 2.5, and 3.0 volts. Using prior art as shown in FIG. 12c, the cells are stacked in series to give 8.0 volts if their currents are the same; a1=a2=a3=a4. This constrains the voltages that can be chosen.

The invention is shown in FIG. 12d. Because of the symmetrical nature of the sunlight curve, there is not much light going to cells 1 & 4. Noting that v4+v1 approximately equal v3+v2, or in this example 1.0v+3.0v=1.5v+2.5v. This makes it possible to stack cells 1 & 4 in series and cells 2 & 4 in series to get a commonly connected 4.0 volts. The current requirement then is a1=a4 and a2=a3, which is what the solar curve naturally provides.

FIG. 12d is of the cells shown as boxes whose height is the cell's voltage and current is the width of the boxes. In the prior art the cells are connected in series with the same current. The series-parallel invention puts cells 2 & 3 in series and 1 & 4 in series and then connects them in parallel

### Final Preferred Embodiment

### Wide Band

A 10 micron layer of dichromated gelatin (DCG) on a glass substrate is exposed with 100 mw/cm² of 497.9 nm Ar laser light at a half angle theta of 10 degrees. If a stronger Ar laser line like 488 nm is desired for efficiency, then the exposure angle is 10 degrees times 488/500. A first exposure is made after tilting one mirror of the exposure setup by 0.2 degree down and a second exposure is made after tilting the same mirror up the same amount. After standard DCG development in water and alcohol, the grating is combined with a Fresnel lens to image a uniform wide-band spectrum. GaInN solar cells are placed in the blue and green regions of the spectrum, GaAs is placed in the red, and silicon in the un-diffracted image (U).

### Narrow Band

A 50 micron, layer of dichromated gelatin (DCG) on a glass substrate is exposed with 200 mw/cm² of 514.5 nm Ar laser light (green) at a half angle theta of 10 degrees. As in the wideband embodiment, a first exposure is made after tilting one mirror of the exposure setup by 0.2 degree down and a second exposure is made after tilting the same mirror up the same amount. The hologram is then rotated 180 degrees about its perpendicular axis and a second exposure pair, like the 514.5 nm exposures, is made using 20 mw/cm² of the 457.9 nm line (blue) of the argon laser. After standard DCG development in water and alcohol, the grating is combined with a Fresnel to image a green and a blue spot of light on opposite sides of the optical axis. GaInN solar cells are placed in these blue and green spots, and GaAs is placed in the orange un-diffracted image (U).

This invention has been described with reference to particular embodiments. It will be understood to those skilled in the art that this invention is also capable of a variety of further embodiments within the spirit and scope of the claims.

1. A hologram with a Fresnel lens to concentrate and spectrally split solar light.

2. Uniform placement of sunlight on solar cells.

3. Electrically connecting solar cells to obtain uniform output.
